(19) United States
(12) Patent Application Publication
(10) Pub. No.: US 2009/0228763 A1
(43) Pub. Date: Sep. 10, 2009

(54) METHOD AND APPARATUS FOR ENCODING AND DECODING DATA WITH ERROR CORRECTION

(75) Inventor: Jin Wang, Shanghai (CN)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 12/305,214

(22) PCT Filed: Jun. 26, 2007
(86) PCT No.: PCT/IB07/52461

§ 371 Date: Dec. 17, 2008

(30) Foreign Application Priority Data
Jun. 29, 2006 (CN) 200610095689.6

(51) Int. Cl. H03M 13/00; G06F 11/00

(52) U.S. Cl. 714/776; 714/701; 714/E11.179

(57) ABSTRACT

The invention provides a method and apparatus for encoding and decoding data with error correction. In a data packet of a video stream, important data may be discarded because the total number of errors of important data and normal data exceeds a limit, even though important data itself has no or little error. To avoid that important data is influenced by errors of normal data, a data packet with important data being as information data is generated by the invention, and other data bits in the data packet are filled with non-information data. When decoding the video data stream, non-information data is firstly recovered to the data with no error. Therefore the important data can be error corrected and will not be discarded if the number of errors of important data itself does not exceed a specific error number limit, thereby increasing the error correction ability to the important data.

### FIELD OF THE INVENTION

The present invention relates to the field of data correction, in particular to a method and apparatus for encoding and decoding data with error correction.

### BACKGROUND OF THE INVENTION

In the development of digital television and optical storage technique, various digital encoding and decoding technique standards with low code rate and high quality have been developed to adapt to various technical needs. However, data error in the process of digital encoding, transmission and decoding still can not be avoided, thus many data error correction methods have been developed.

Bit errors in a video stream mainly occur in the process of data storage and transmission. The occurrence of a data error generally causes an out of sync between audio and video stream data, thus influences decoding and playing of a video stream program. Reed-Solomon error correction code is a data error correction scheme widely used in data storage and transmission.

In a broadcast level application, a data packet of a data transport stream comprises a data of 188 bytes. At the encoding end, RS encoder adds an error correction redundant information of 16 bytes in a data packet; at the decoding end, error correction is performed for the information data in a data packet through the error correction redundant information. In general, error correction can be performed by RS encoding error correction scheme for a data packet with the number of errors less than 8. If the number of errors in the information data in a data packet exceeds 8, RS encoding error correction scheme can only give up the error correction for the data packet, and all information data in the data packet will also be discarded correspondingly.

Different types of data information in a video data stream have different importance. US patent application US2005/0076272A1 discloses a technical solution of providing different error correction protections depending on different data types. The technical solution uses a single RS code for all data information. If RS error correction redundant information has to be reduced, however, only the error correction information of information data of higher importance is preserved, and one or more pieces of error correction information generated by information data of lower importance will be ignored.

### OBJECT AND SUMMARY OF THE INVENTION

One object of the present invention is to provide a method and apparatus for encoding and decoding data with error correction.

According to an embodiment of the invention, a method for encoding data with error correction is provided, the method comprises steps of: acquiring a type information of a data; determining whether the data belongs to a predefined type or not based on the type information; generating a data packet of a specific length, with the data serving as information data, and filling other data bits in said data packet with non-information data, if the data belongs to said predefined type; and encoding said data packet with error correction.

According to an embodiment of the invention, an apparatus for encoding data with error correction is provided, the error correction apparatus includes: an acquiring unit, for acquiring the type information of a data; a determining unit, for determining whether the data belongs to a predefined type or not based on said type information; a generating unit, for generating a data packet of a specific length, with the a whole or part of the data serving as information data, and filling other data bits in said packet with non-information data, if said data belongs to said predefined type; and an encoding unit, for encoding said data packet with error correction.

Said predefined data type mainly includes header information data type, and other important data types such as navigation information data type, etc. Header information data is, for example, elementary stream header information, sequence header information, GOP (group of pictures) header information, and picture header information, etc. Navigation data is, for example, data search information (DSI), presentation control information (PCI), etc. If a data belongs to a predefined type, the data belongs to important information and should be specially protected.

Data amount of the information data in the generated data packet may be constant, such as 60 bytes. Correspondingly, if the data amount of said data is larger than the constant data amount, only part of the information in the data may serve as information data in the data packet, and the rest of the information may serve as information data in other data packets. If the data amount of said data is less than the constant data amount, the information data in the packet comprises, in addition to the data, other data belonging or not belonging to a predefined type.

Data amount of the information data in the generated data packet may also be variable, but it should be less than a certain data amount, such as 60 bytes, otherwise the information data belonging to a predefined type can not be protected efficiently.

Said non-information data can be invalid data recognized by the system, such as OXFF and so on in the prior art. Said specific amount of length of the data packet is specified by standards such as data compression, for example, the length of a data packet (including the header information) is 188 bytes, etc. Encoding said data packet with error correction is encoding said data packet in a manner of adding redundant error correction information, such as RS error correction encoding, to generate a program stream for storage or a transport stream for a broadcast system.

According to an embodiment of the invention, a method for decoding data with error correction is provided, the method includes steps of: acquiring a description information of a data packet; identifying non-information data in said data packet based on said description information of the data packet; determining whether said non-information data conforms to a specific format; correcting said non-information data to said specific format, if said non-information data does not conform to said specific format; and error correction decoding said data packet comprising information data and non-information data conforming to a specific format.

According to an embodiment of the invention, an apparatus for decoding data with error correction is provided, the apparatus includes: an acquiring unit, for acquiring the description information of a data packet; an identifying unit, for identifying non-information data in said data packet based on said description information of the data packet; a determining unit, for determining whether said non-information data conforms to a specific format or not; a correcting unit, for correcting said non-information data to said specific format, if said non-information data does not conform to said specific format; and a decoding unit, for error correction decoding said data packet comprising information data and non-information data conforming to a specific format.

Said description information of a data packet comprises description of the data in the data packet, such as data amount, number of bits and location of the information data, number of bits and location of the non-information data, data format of the non-information data, etc. In the process of storing and transmitting a data, data error is unavoidable due to interference. Error is also unavoidable for a non-information data with a specific format. The non-information data with errors will no longer conform to a specific format, for example, the specific format of a non-information data is 0XFF, it may become 0XEF after error occurs. The decoding apparatus can correct an error data to the data conforming to a specific format, i.e. 0XFF, before decoding the data packet.

Decoding said data packet with error correction refers to decoding the data in the data packet based on the error correction redundant information in the data packet. Because there is no error in the corrected non-information data, the error correction redundant information in the data packet is used only for the information data, thus improving error correction effect on the information data.

By the method and apparatus provided by the invention for encoding and decoding a data with error correction, the bits of information data in a data packet is limited to a small number and filled only with important information such as header information, and other data bits in the data packet are filled with non-information data. Since encoding with error correction is not applied to non-information data when a video data stream is channel decoded, if the error amount of the important data itself does not exceed a specific error amount limit, the important data can be corrected and will not be discarded.

Other objects and advantages of the invention will become apparent and a full understanding of the invention will be obtained from the following description and claims with reference to accompanying figures.

### BRIEF DESCRIPTION OF THE DRAWINGS

The invention will be further explained in detail through embodiments, with reference to accompanying drawings, wherein:

FIG. 1 is the flow chart of a method for encoding data with error correction according to an embodiment of the invention;

FIG. 2 is the block diagram of an apparatus for encoding data with error correction according to an embodiment of the invention;

FIG. 3 is a schematic drawing of an encoding process according to the invention;

FIG. 4 is the flow chart of a method for decoding data with error correction according to an embodiment of the invention;

FIG. 5 is the schematic block diagram of an apparatus for decoding data with error correction according to an embodiment of the invention.

In all the above figures, the same signs represent the same, similar, or corresponding features or functions.

### DETAILED DESCRIPTION OF THE INVENTION

The concept of the invention is as follows: in a data packet of a video stream, if the total number of data errors exceeds the maximum error number allowed by Reed-Solomon error correction method, the data packet will be discarded. A discarded data packet may comprise both normal data (e.g. picture data) and important data (e.g. header information data). Even though there is no or little error in the important data itself, it may be discarded because the total number of errors in it and errors in the normal data exceeds the limit. To avoid that important data is influenced by errors of normal data, the bits of the information data in a data packet is limited by the invention to a small number and are filled only with important information such as header information, while other data bits in the data packet are filled with non-information data. Non-information data will be firstly corrected to data with no error when the video data stream is channel decoded, so if the number of errors in the important data itself does not exceed a specific error amount limit, the important data can be corrected and will not be discarded.

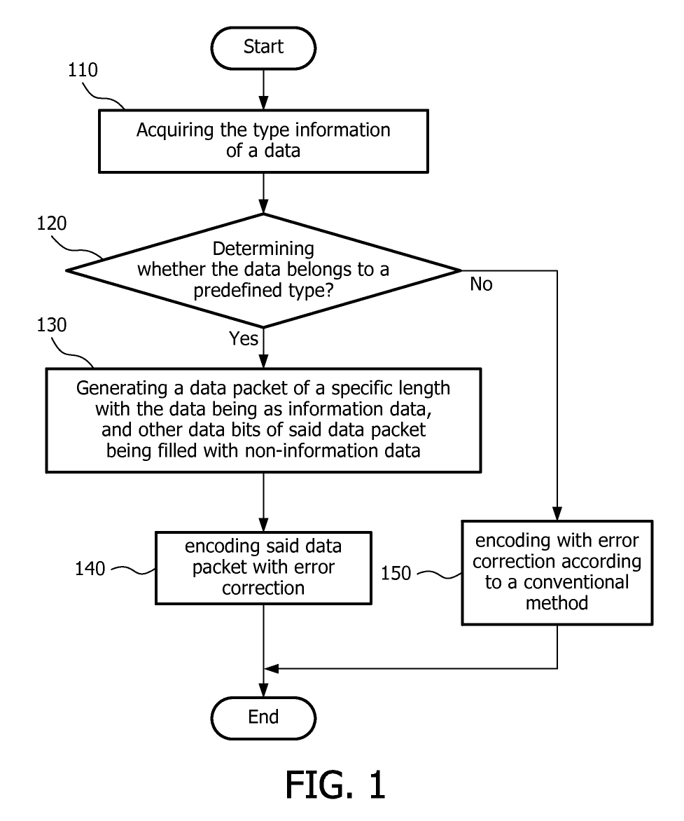

FIG. 1 is the flow chart of a method for encoding data with error correction according to an embodiment of the invention. Firstly, a type information of a data to be processed is acquired (110). The data to be processed comprises video elementary stream information to be multiplexed, etc. In the prior art, video elementary stream information, before being multiplexed with audio data, should be divided into packetized elementary stream (PES) according to a specific byte number. For example, a data packet of a transport stream is formed by using some bytes as information data in a data packet and further adding a data packet header information, e.g. a header information of four bytes.

In a video elementary stream, different data has different types. For example, the GOP (group of pictures) header information in a video stream characterizes information of individual picture data type, location, size and other description information, etc. of the group of pictures. The picture header information data describes the basic feature information of said picture data. Again, for example, picture data is the data bearing picture information. Different picture data is of different types, and different importance accordingly, such as I frame data, B frame data and P frame data.

Secondly, it is determined that whether the type of the data belongs to a predefined type (120). Different types of data have different importance. The header information data plays important roles to the data in the whole data packet it leads, such as navigation, addressing, decoding. If the header information is destroyed or presents errors that could not be corrected, the data it leads can't be used. If an I frame picture data can not be corrected, any B frame and P frame picture referring to the I frame picture can not be displayed, either. If a B frame picture data has an error that can not be corrected or is destroyed, the picture could not be displayed, but its influence on other pictures is small.

To protect important data, the header information of each data packet and other important information such as header information in the data packet are made predefined types that require special protection. Based on the type information of the data acquired in step 110, it can be determined whether the data belongs to a predefined data type.

If the type of a data belongs to a predefined data type, a data packet is generated with the data being as an information data (130), and other data bits in the data packet generated are filled with non-information data. A data packet of the invention includes data units that can be stored or transported independently, such as data packet. That a data packet is generated with the data being as an information data means that in the data packet, said data is valid information content or the data is main information content.

According to the data compression standard, a data packet has a specified length, i.e. it has a specific amount (or bytes) of data, e.g. 184 bytes. In the invention, the data packet with said data being as information data also must satisfy the data amount requirement set by the standard. In general, byte number of important information such as header information, is small, and can not satisfy the byte number required by a data packet. In order that both the data amount requirement is satisfied and important data is not influenced by errors of other data in a data packet, other data bits in a data packet are filled with non-information data, e.g. non-information data 0XFF, by the invention. A data packet comprising information data and non-information data, plus the header information (e.g. 4 bytes) of the data packet, become a data packet that can be encoded with error correction.

Even though byte number of the header information can reach the length required for a data packet, byte number of the header information data in the data packet should be reduced to a suitable amount and other bytes are filled with non-information data, in accordance with the invention. Exceeding number of bytes of the header information can be served as information data in another data packet.

The data packet comprising said information data and non-information data is encoded with error correction (140). Encoding with error correction is that channel encoding is performed to said data packet so that errors generated in the process of transporting or storing said data packet can be corrected. Reed-Solomon error correction encoding method can be employed for encoding with error correction, data in a data packet is calculated crosswise, an error correction redundant information of 16 bits is added. A data packet that has been encoded with error correction can be used for data storage and transportation.

According to the invention, at the decoding end, before decoding with error correction, the decoding apparatus can firstly correct to a state of no error through the description information of a data packet, so the total number of errors of the data packet only (or mainly) includes the number of errors of information data, i.e. the number of errors of important data, thus the influence of errors of other data on the important data is avoided or reduced.

According to the invention, number of bits of information data in a data packet, in which important data is used as information data, can be specified, such as 60 bytes. If the byte number of an important data exceeds 60 bytes, the important data can be divided into several important data of not more than 60 bytes, to respectively constitute information data in several data packets. If byte number of the important information is less than 60 bytes, the number of the remaining bytes can be filled with normal data suitably, or with non-information data, of course. Byte number of important data in a data packet can be specified in header information of the data packet. The decoding apparatus can identify information data and non-information data based on the identification information such as description information of the data packet when decoding.

After the determination, if the type of the data is not a predefined type, the data is normal data and does not need to be specially protected, and it only needs to be encoded with error correction to a data packet according to a conventional method (150). According to the conventional method, except that the last data packet may include some non-information data due to lack of data, all data in other data packets is information data, such as picture data.

By means of the above method provided by the invention for encoding with error correction, important data in a data stream can be protected sufficiently and will not be influenced by other data errors, unless the number of errors in the important data itself exceeds the maximum error number allowed.

In the prior art, a data elementary stream is divided into several data packets sequentially from front to end. If data amount in the last data packet can not satisfy the data amount required by the standard, non-information byte, e.g. 0XFF, should be filled. In the present invention, however, wherever in a data stream if there is an important data to be specially protected, a data packet will be generated with the important data being as information data, and other data bits are filled with non-information data.

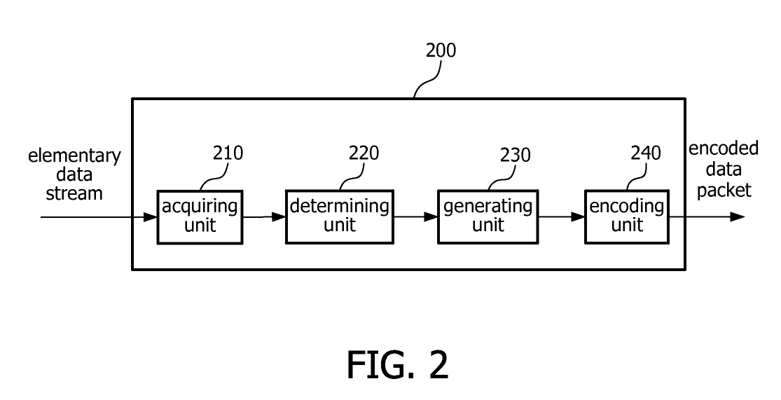

FIG. 2 is a schematic block diagram of an apparatus 200 for encoding data with error correction according to an embodiment of the invention. The apparatus 200 for encoding data with error correction provided by the invention comprises an acquiring unit 210 for acquiring the type information of a data. In a data stream, e.g. a video elementary stream, different data has different types.

The apparatus 200 further comprises a determining unit 220 for determining whether the type of the data belongs to a predefined type. Different types of data have different importance. To protect important data, header information and important data types, such as other header information, of each data packet are made predefined types that require special protection.

The apparatus 200 further comprises a generating unit 230 for generating a data packet with the data being as information data and filling other byte bits of the generated data packet with non-information data, if the type of the data belongs to the predefined type. Said data packet has a specific data length, i.e. it has a specific amount of data.

The data packet described by the invention comprises data units that can be stored or transported independently, such as data packet. That a data packet is generated with the data being as information data means that in the data packet said data is valid information content or is main information content.

The apparatus 200 further comprises an encoding unit 240 for encoding said data packet with error correction. Encoding with error correction is that said data packet is channel encoded in order that errors generated in the process of storing or transporting said data packet can be corrected. Reed-Solomon error correction encoding method can be employed for encoding with error correction, the data in a data packet is calculated crosswise, an error correction redundant information of 16 bits is added. A data packet that has been encoded with error correction can be stored and transported.

At the decoding end, before decoding with error correction, the decoding apparatus can firstly correct non-information data to a state of no error by means of the description information of a data packet, and then decode the entire data packet with error correction, so the total number of errors of the data packet only (or mainly) includes the number of errors of information data, i.e. the number of errors of important data, and thus the influence by errors of other data on the important data is avoided or reduced.

According to the apparatus provided by the invention for encoding data with error correction, important data in a data stream can be protected sufficiently and will not be influenced by errors of other data, unless the number of errors of important data itself exceeds the maximum error number allowed.

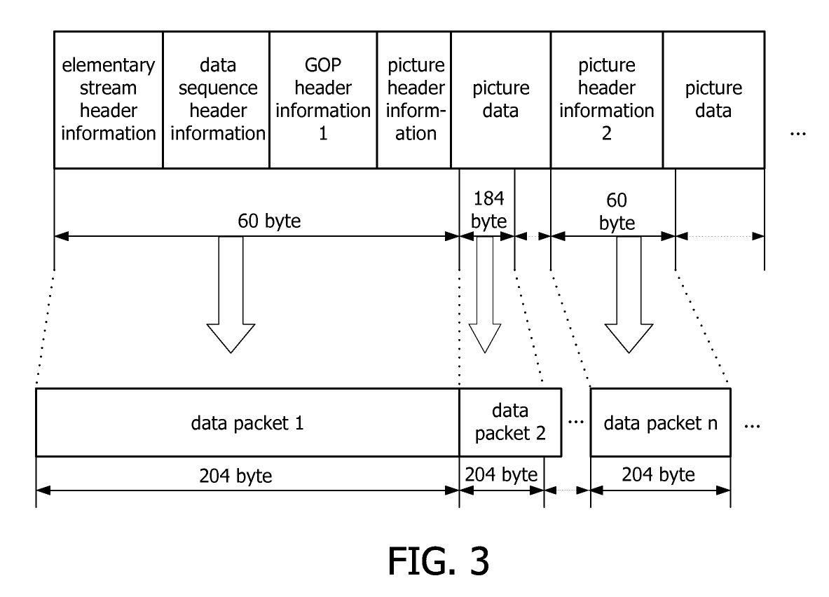

FIG. 3 is the schematic drawing of an encoding process according to the invention. As shown in FIG. 3, an elementary stream data comprises elementary stream header information, data sequence header information, GOP (group of pictures) header information, picture header information, picture data, etc.

In this example, it is assumed that if the information content in a data packet is of a predefined type, i.e. important information such as header information, then the total byte number of information data of the data packet is 60 bytes, in which the information data mainly comprises important information, and other information data, such as picture data. When decoding, the decoding apparatus can determine the specific 60 bytes in a data packet to be as information data based on header information of the data packet, and ignore other data.

In general, the total byte number of elementary stream header information, data sequence header information, GOP (group of pictures) header information, picture header information is not less than 40 bytes and can reach 164 bytes sometimes. If the total size of header information is 40 bytes, to complement the defined byte number of the information data, a picture data of 20 bytes can be added into the information data. In the case shown in FIG. 3, the size of the elementary stream data header information is less than 60 bytes, and it is still less than 60 bytes after the following header information (data sequence header information, GOP (group of pictures) header information, picture header information) has been added, then the information data becomes 60 bytes after a part of picture data has been added.

If the header information data is 164 bytes, it can be divided into 3 data segments, which constitute the information data of three data packets respectively. The first and second data packets comprise a header information of 60 bytes respectively, the third data packet comprises a header information data of 44 bytes and a picture data of 16 bytes. Of course, the header information data also can be divided in other ways, e.g. it is divided into three segments of header information data equally or according to the type of the header information, etc.

As shown in FIG. 3, an encoded transport stream data packet of 204 bits is formed after the information data of 60 bytes is added with a data packet header information of 4 bytes, a non-information data 0XFF of 124 bytes, and then an error correction redundant data of 16 bytes through RS encoding with error correction. The data packet header information of 4 bytes comprises information such as location, number of bits of the information data in the data packet.

Data with normal importance, such as picture data, is encoded in sequence, i.e. every 184 picture data bytes constitute the information data in a data packet, it is added with a data packet header information of 4 bytes and then is encoded with RS error correction to form an encoded transport stream data packet of 204 bytes.

In the embodiment shown in FIG. 3, encoding picture header information 2 is also that the header information plus part of picture data totaling 60 bytes, are made as valid information data in a data packet. An encoded transport stream data packet of 204 bytes will be formed after it is added with a data packet header information of 4 bytes and a non-information data F of 124 bytes, and then is RS encoded with error correction.

In the embodiment shown in FIG. 3, if byte number of the information data in a data packet is not defined, each important data, such as header information, can be made as the only information data in a data packet, for example only the elementary stream header information is made as the information content of a data packet, all the other bytes are filled with non-information data.

When decoding, according to the header information of the data packet, the decoding apparatus can determine the location, number of bits and so on of the information data and non-information data, correct firstly the non-information data to a no error state, and perform error correction on the entire data packet based on Reed-Solomon error correction code. If the errors in the information data itself are not more than 8, errors in the information data can be corrected by RS error correction coding.

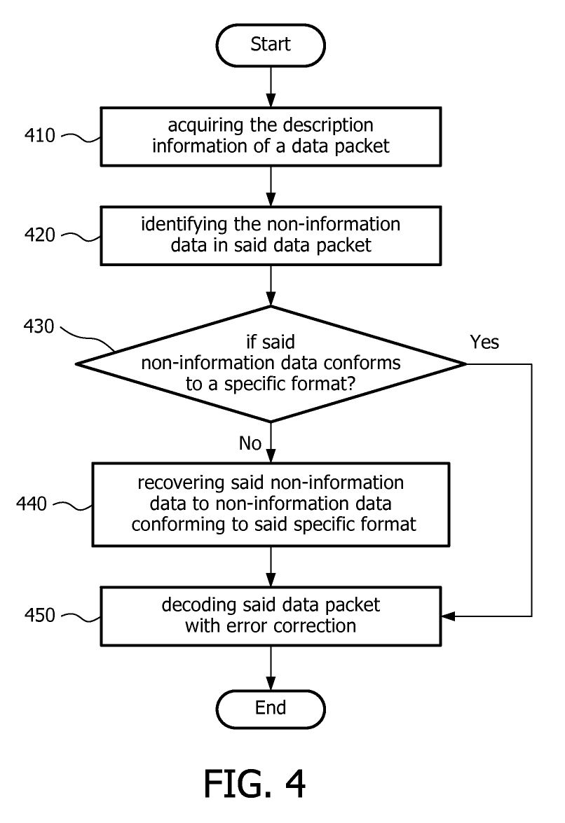

FIG. 4 is the flow chart of a method for decoding data with error correction according to an embodiment of the invention. Firstly, the description information of a received data packet to be decoded is acquired (410). The description information of the data packet comprises description of effective length of the data packet, description of data in the data packet, such as location, number of bits of the information data, and location, number of bits, and format of the non-information data.

Secondly, non-information data in said data packet is identified based on the description information acquired (420). The description information of the data packet can guide the decoding apparatus to identify the non-information data thereof and its number of bits, location and format, etc.

Then, it is determined whether the non-information data identified conforms to a specific format or not (430). It can be determined whether the non-information data in said data packet conforms to the format it should have by comparing the format of non-information data in the data packet with the format that the non-information data provided in the description information of the data packet should have. Format of the non-information data can also be a general format or a format defined by the standard, without being defined specifically in the description information of the data packet.

If the format of the non-information data does not conform to the specific format, it shows that errors occurred in the non-information data in the process of storing and transporting the data, the decoding apparatus would firstly correct the non-information data with error to a no error state (440). For example, non-information data 0XFF became 0XEF in the process of storing or transporting, the decoding apparatus will correct 0XEF to 0XFF before decoding.

Last, if the format of the non-information data conforms to the specific format or conforms to the specific format after the correction, the data packet is decoded with error correction (450) in the case that all the non-information data has no error. After the non-information data with error having been corrected to a no error state, there may be error only in the information data in said data packet, so the error correction redundant information added during the process of encoding with error correction only performs error correction on the information data, thereby increasing the error correction ability to the information data and providing good protection for the information data.

According to the method provided by the invention for decoding with error correction, and in conjunction with the method provided by the invention for encoding with error correction, important data in a data stream can be protected efficiently with error correction.

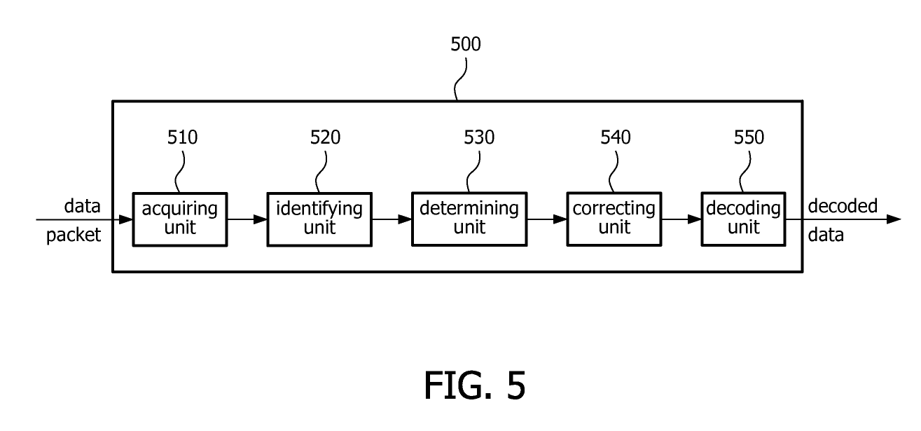

FIG. 5 is the schematic block diagram of an apparatus 500 for decoding data with error correction according to an embodiment of the invention. The apparatus 500 includes an acquiring unit 510. The acquiring unit 510 acquires the description information of a data packet to be decoded. The description information of the data packet comprises description of the data in the data packet, such as location, number of bits of the information data, and location, number of bits, and format and so on of the non-information data.

The apparatus 500 further includes an identifying unit 520. The identifying unit 520 identifies the non-information data of said data packets based on the description information acquired. The description for the non-information data in the description information of the data packet can guide the decoding apparatus to identify the non-information data thereof and the location, number of bits and so on of the non-information data.

The apparatus 500 further includes a determining unit 530. The determining unit 530 determines whether the non-information data identified conforms to a specific format or not based on the format of the non-information data (430). It can be determined whether the non-information data in said data packet conforms to the format it should have by comparing the format of the non-information data of the data packet with the format that the non-information data provided in the description information of the data packet should have. The format of the non-information data may also be a general format or a format defined by the standard, and without being defined specifically in the description information of the data packet.

The apparatus 500 further includes a correcting unit 540. If the format of the non-information data does not conform to the specific format, it shows that errors occurred in the non-information data during the process of storing and transporting the data, the decoding unit firstly corrects the non-information data with error to a no error state (440). For example, non-information data 0XFF became 0XEF during the process of storing or transporting, the decoding unit will correct 0XEF to 0XFF before decoding.

The apparatus 500 further includes a decoding unit 550. The data packet is decoded with error correction by the decoding unit 550 if all the non-information data has no error. After the non-information data with error having been corrected to a no error state, there may be error only in the information data in said data packet, so the error correction redundant information added during the process of encoding with error correction only performs error correction on the information data, thereby increasing the error correction ability to the information data and providing good protection for the information data.

In the prior art, if a lot of other data such as picture data is also protected in addition to the header information in a data packet, the data packet should be discarded when the number of errors of the picture data exceeds a specific amount, for example 8, even though there is no error in the header information data, and all the data information led by the header information would not be available and have to be discarded. Compared with the prior art, the special protection to the important data provided by the invention can ensure that the important data is not influenced by the errors of other data.

Although the invention has been described in conjunction with embodiments, various replacements, modifications, and variants of the described contents will be apparent to those skilled in the art. Therefore, all such replacements, modifications and variations should fall into the spirit and scope of the claims of the invention.

1. A method for encoding data with error correction, the method comprises steps of:
acquiring a type information of a data;
determining whether the data belongs to a predefined type or not based on said type information;
generating a data packet of a specific length with said data being as information data and filling other data bits of said data packet with non-information data, if said data belongs to said predefined type; and
encoding said data packet with error correction.

2. The method as claimed in claim 1, wherein, said type information includes at least one of: header information data type, navigation data type and picture data type.

3. The method as claimed in claim 1, wherein, said predefined type includes at least one of: header information data type and navigation information type.

4. The method as claimed in claim 1, wherein, said non-information data is non-information data of a specific format as defined by a data encoding standard.

5. The method as claimed in claim 1, wherein, the information data of said data packet has a fixed length.

6. The method as claimed in claim 5, wherein, the information data of said data packet comprises a part of data not belonging to said predefined type.

7. An apparatus for encoding data with error correction, the error correction apparatus includes:
an acquiring unit, for acquiring the type information of a data;
a determining unit, for determining whether said data belongs to a predefined type or not based on said type information;
a generating unit, for generating a data packet of a specific length with the data being as the information data and filling the other data bits in said data packet with the non-information data, if said data belongs to said predefined type; and
an encoding unit, for encoding said data packet with error correction.

8. The apparatus for encoding with error correction as claimed in claim 7, wherein, said type information includes at least one of: header information data type, navigation data type and picture data type.

9. The apparatus for encoding with error correction as claimed in claim 7, wherein, said predefined type includes at least one of: header information data type and navigation information type.

10. The apparatus for encoding with error correction as claimed in claim 7, wherein, said non-information data is non-information data of a specific format as defined by a data encoding standard.

11. The apparatus for encoding with error correction as claimed in claim 7, wherein, the information data in said data packet has a fixed length.

12. The apparatus for encoding with error correction as claimed in claim 11, wherein, the information data in said data packet comprises a part of data not belonging to said predefined type.

13. A method for decoding data with error correction, the method comprises steps of:
acquiring a description information of a data packet;
identifying a non-information data in said data packet based said description information of the data packet;
determining whether said non-information data conforms to a specific format or not;
recovering said non-information data to said specific format if said non-information data does not conform to said specific format; and
decoding with error correction said data packet comprising the information data and said non-information data conforming to said specific format.

14. The method as claimed in claim 13, wherein, said description information of the data packet comprises the description for said non-information data.

15. The method as claimed in claim 14, wherein, the description for said non-information data includes at least one of: format description of the non-information data, number of bits of the non-information data and location of the non-information data.

16. The method as claimed in claim 13, wherein, said specific format of said non-information data includes format of non-information data according to a data compression standard.

17. An apparatus for decoding data with error correction, the apparatus includes:
an acquiring unit, for acquiring a description information of a data packet;
an identifying unit, for identifying a non-information data in said data packet based said description information of the data packet;
a determining unit, for determining whether said non-information data conforms to a specific format or not;
a correcting unit, for correcting said non-information data to said specific format if said non-information data does not conform to said specific format; and
a decoding unit, for decoding with error correction said data packet comprising information data and said non-information data conforming to said specific format.

18. The apparatus as claimed in claim 17, wherein, said description information of the data packet comprises the description for said non-information data.

19. The apparatus as claimed in claim 18, wherein, the description for said non-information data includes at least one of: format description of the non-information data, number of bits of the non-information data, and location of the non-information data.

20. The apparatus as claimed in claim 17, wherein, said specific format of said non-information data includes format of non-information data according to a data compression standard.
